(19) United States
(12) Patent Application Publication
(10) Pub. No.: US 2011/0041040 A1
(43) Pub. Date: Feb. 17, 2011

(54) Error Correction Method for a Memory Device

(75) Inventors: Chin-Jung Su, Hsinchu (TW); Chuang Cheng, Hsinchu (TW)

Correspondence Address: SQUIRE, SANDERS & DEMPSEY L.L.P., 275 BATTERY STREET, SUITE 2600, SAN FRANCISCO, CA, 94111-3356, US

(73) Assignee: SKYMEDI CORPORATION, Hsinchu (TW)

(21) Appl. No.: 12/541,944

(22) Filed: Aug. 15, 2009

(51) Int. Cl. H03M 13/05; G06F 11/10

(52) U.S. Cl. 714/773; 714/E11.032; 714/782; 714/780

(57) ABSTRACT

An error correction method for a memory device is disclosed. A base reading of a memory device is performed, and an error correction code (ECC) decoding is performed on the data read out of the memory device. The memory device is further read when the result of the ECC decoding is not strongly determined, wherein extra information acquired in the further reading of the memory device is used in the ECC decoding.

### BACKGROUND OF THE INVENTION

1. Field of the Invention

The present invention generally relates to a storage device, and more particularly to an error correction method for a memory device.

2. Description of the Prior Art

Error detection and correction is important in maintaining data reliability in a storage device such as a semiconductor-based memory device. This fact becomes more significant as either the density or the number of bits stored in each memory cell increases. Moreover, the semiconductor-based memory device such as a flash memory may have bad bits that are either produced during the manufacturing or arose from substantial cycles of read and write.

Error correction code (ECC) is therefore used to improve the reliability in the memory device. However, the ECC in the conventional memory device is not effective. For the worse, when the number of errors exceeds the capability of the error correction scheme, the data stored in the memory device no longer can be recovered and are lost forever.

For example, the conventional flash memory usually employs low-density parity-check (LDPC) coding and associated soft-decision decoding technique in correcting error(s) of the data bits. However, the LDPC and associated soft-decision decoding no longer can recover the erroneous data when the number of error bits exceeds the capability of the error correction.

Furthermore, the threshold voltage distribution of the flash memory may probably change or drift after the flash memory has been subjected to a number of program/erase cycles or/and certain data retention time has elapsed. Errors probably incur if the threshold read value does not change correspondingly according to the change of the threshold voltage distribution.

For the reason that the conventional memory device such as the flash memory could not effectively correct error(s) and prevent data loss, a need has arisen to propose a novel error correction method for substantially improving capability of error correction in the memory device.

### SUMMARY OF THE INVENTION

In view of the foregoing, it is an object of the embodiments to provide an error correction method for a memory device such as a flash memory in order to substantially improve the capability of error correction in the memory device.

According to one embodiment, a memory device is firstly (base) read, and the soft values associated with data bits read out of the memory device are initialized. At least one iteration of error correction code (ECC) decoding is performed on the soft values, and the soft values are updated with respect to each iteration of the ECC decoding. Each updated soft value is determined whether it is strong or not. The memory device is further read when not all the updated soft values are strong. Subsequently, the soft values are modified according to read-out data bits of the further reading and the updated soft values.

### BRIEF DESCRIPTION OF THE DRAWINGS

FIG. 1A is a flow diagram that illustrates an error correction method for a memory device according to one embodiment of the present invention;

FIG. 1B is a timing diagram that schematically shows an exemplary LDPC operation for reading a flash memory;

FIG. 1C is a timing diagram that schematically shows another exemplary LDPC operation for reading a flash memory;

FIG. 1D is a timing diagram that schematically shows a further exemplary LDPC operation for reading a flash memory;

FIG. 2A is a detailed flow diagram that illustrates an error correction method for a memory device according to the embodiment of the present invention;

FIG. 2B shows initial, intermediate, and final results of reading an exemplary byte out of the flash memory according to the steps disclosed in FIG. 2A; and

FIG. 2C is a detailed flow diagram that illustrates an error correction method for a memory device according to a modified embodiment of the present invention.

### DETAILED DESCRIPTION OF THE INVENTION

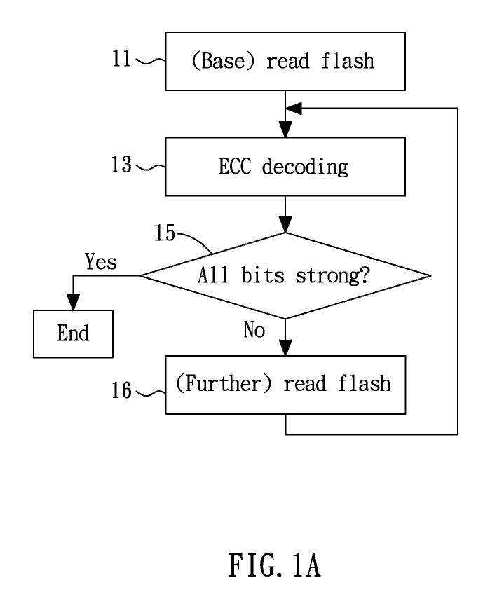

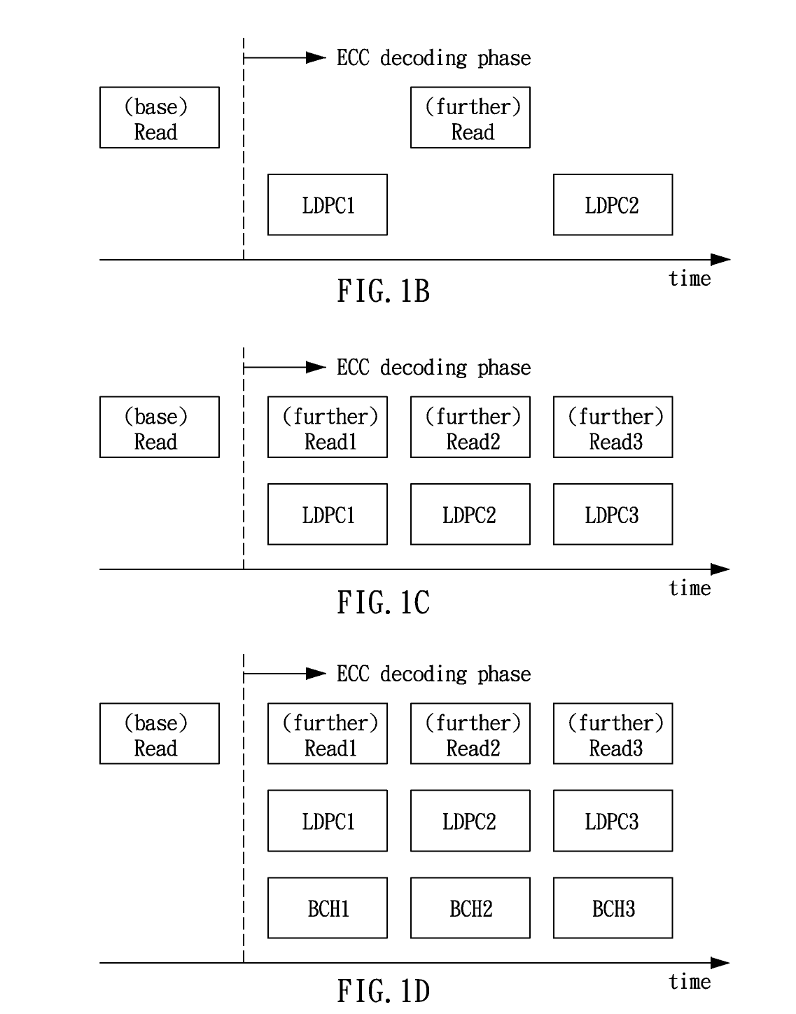

FIG. 1A is a flow diagram that illustrates an error correction method for a memory device according to one embodiment of the present invention. The memory device may in general be any storage device or storage medium, and may specifically be a flash memory in the embodiment. The flash memory is one type of a non-volatile solid state memory device that can be electrically erased and reprogrammed. The flash memory may be capable of storing a single bit of information in each memory cell of a single-level cell (SLC) flash memory, or be capable of storing two or more bits of information in each memory cell of a multi-level cell (MLC) flash memory. Low-density parity-check (LDPC) (a code originally developed in 1960 by Robert Gallager) is utilized as an exemplary, but not limiting, error correction code (ECC) for improving capability of error correction in the flash memory. The LDPC is one type of iterative coding that commonly performs a number of iterations during an ECC decoding phase.

Referring to FIG. 1A, the flash memory is firstly (base) read in the step 11, followed by performing ECC decoding in the step 13. Whenever the result of the ECC decoding cannot be firmly or strongly determined (the step 15), for example not all bits are strong, the flash memory is further read (in the step 16) to provide extra information that is further used in the ECC decoding (the step 13), finally resulting in firmly decoding output. It is noted that the base flash read (the step 11) may contain two or more iterations preferably, but not necessarily, with different read threshold values respectively. It is also noted that the further flash read (the step 16) may perform more than one time to acquire extra information until a decoding criterion (or strong result) has been reached. It is further noted that at least some extra information may be provided, for example, by previously stored information rather than directly read out of the flash memory. In other words, the extra information may contain the information directly read out of the flash memory, or the previously stored information, or their combination.

FIG. 1B is a timing diagram that schematically shows an exemplary LDPC operation for reading a flash memory. According to FIG. 1B, a further read is performed in the ECC decoding phase, in between LDPC1 and LDPC2, according to one aspect of the present embodiment. FIG. 1C is a timing diagram that schematically shows another exemplary LDPC operation for reading a flash memory. According to FIG. 1C, each LDPC operation performs concurrently with a further read operation. Accordingly, the second LDPC (LDPC2) operation may use information provided by the first further read (Read1), and the third LDPC (LDPC3) operation may use information provided by the second further read (Read2). FIG. 1D is a timing diagram that schematically shows a further exemplary LDPC operation for reading a flash memory. According to FIG. 1D, a further ECC coding such as BCH code (a code named after Bose, Chaudhuri, and Hocquenghem) may be concurrently accompanied with the LDPC coding.

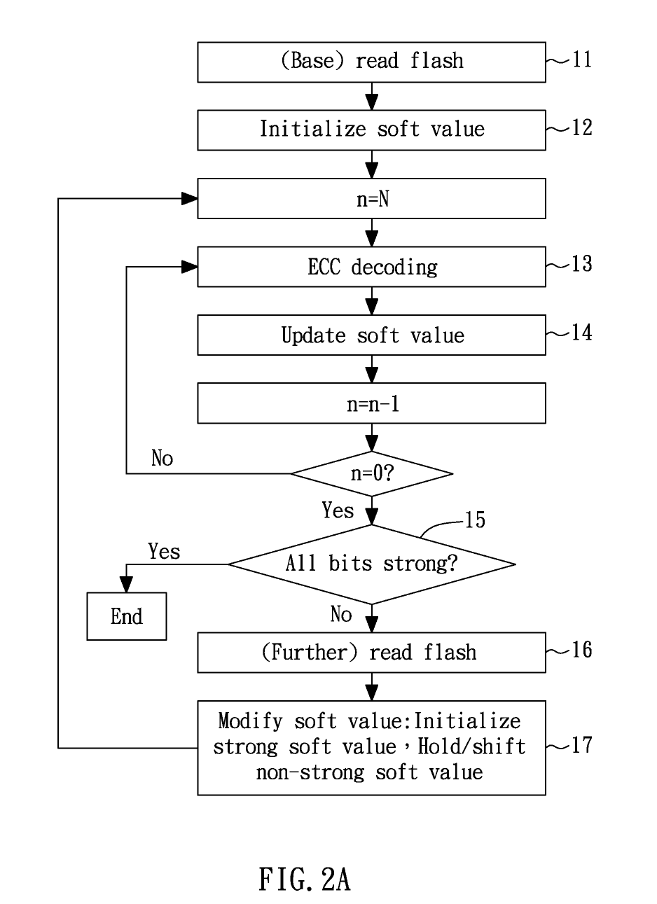

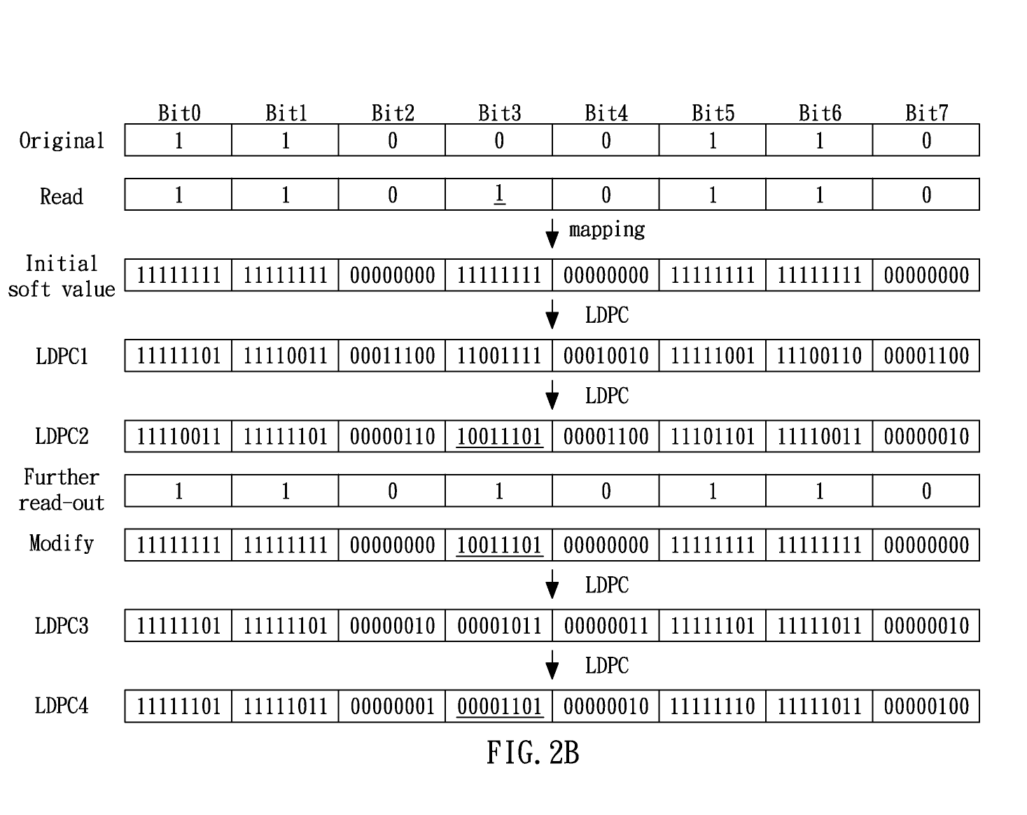

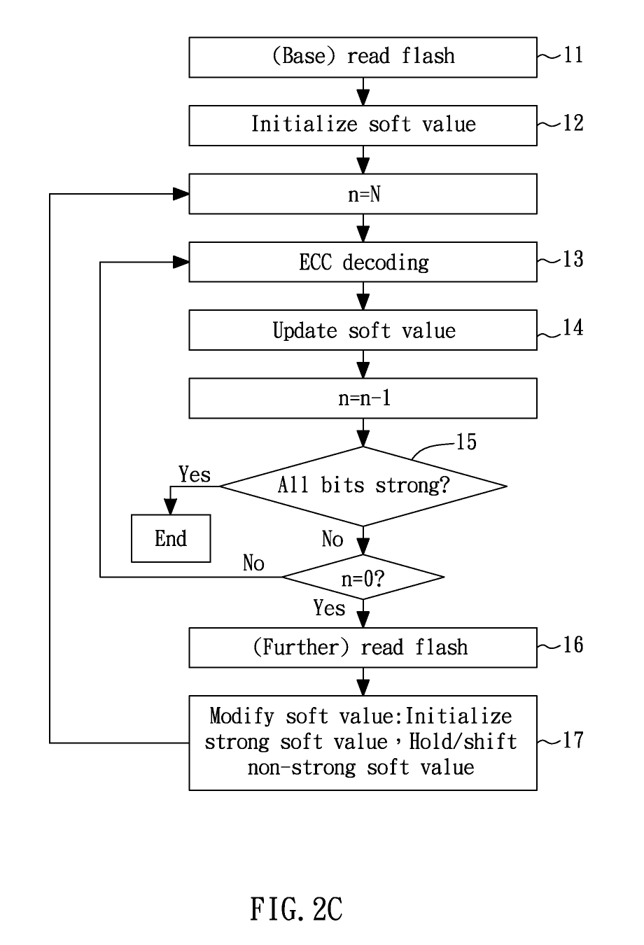

FIG. 2A is a detailed flow diagram that illustrates an error correction method for a memory device according to the embodiment of the present invention. The steps corresponding to those in FIG. 1A are designated with the same numerals. FIG. 2B shows initial, intermediate, and final results of reading an exemplary byte out of the flash memory according to the steps disclosed in FIG. 2A.

In the embodiment, the flash memory is firstly read in the step 11. In the example shown in FIG. 2B, the original data bits (e.g., bit 0 to bit 7) stored in the flash memory are “11000110” and the data bits read out of the flash memory are “11010110.” That is, an error is incurred in the bit 3.

Soft-decision decoding is used in the embodiment. The soft-decision decoding is one type of algorithm used to decode data that have been encoded with ECC. Although soft-decision decoding is used in the embodiment, it is appreciated that other decoding such as hard-decision decoding may be used instead. With respect to the soft-decision decoding, a soft value is associated with each data bit. In the embodiment, the first bit (or the most significant bit) of the soft value is the data bit, and the other bits of the soft value are reliability bits that indicate the reliability of the associated data bit. The soft value may, in the embodiment, be classified into, but not limited to, four categories: strong “1,” weak “1,” weak “0,” and strong “0” as defined in Table 1 (in which an 8-bit system is used).

TABLE 1

| Soft value | | |
|---|---|---|
| (x represents don't | Soft value | |
| care) | Range | Category |
| 11xxxxxx | 11111111-11000000 | Strong “1” |
| 10xxxxxx | 10111111-10000000 | Weak “1” |
| 01xxxxxx | 01111111-01000000 | Weak “0” |
| 00xxxxxx | 00111111-00000000 | Strong “0” |

In the step 12, the soft value of each data bit is initialized to result in an initial soft value. For example, the data bit “0” read out of the flash memory is initialized as (or mapped to) “00000000” (e.g., strong “0”) and the data bit “1” is initialized as (or mapped to) “11111111” (e.g., strong “1”). Please refer to FIG. 2B for the “initialized” read data labeled as the initial soft value. As previously noted that the base reading (the step 11) may perform more than one time, accordingly, each soft value may be initialized in the step 12 according to more than one data bit. Table 2 shows an example in which the initial soft value is determined according to both the first-read data bit and the second-read data bit.

TABLE 2

| First-read data bit | Second-read data bit | Initial soft value |
|---|---|---|
| 0 | 0 | 00000000 |
| 0 | 1 | 00111111 |
| 1 | 0 | 11000000 |
| 1 | 1 | 11111111 |

Subsequently, ECC decoding (i.e., LDPC decoding in this embodiment) is performed in the step 13. In the embodiment, one or more iterations of the ECC decoding are performed. With respect to each iteration in the ECC decoding, the soft value for each data bit is correspondingly updated (in the step 14). In the example shown in FIG. 2B, the soft values are updated as LDPC1 and LDPC2 in sequence.

After a predetermined number (e.g., two in the example) of iterations have been completed, the latest soft values of the data bits are determined in the step 15. It is noted, according to the flow illustrated in FIG. 2A, that N iterations of the ECC decoding step 13 and the soft-value updating step 14 are performed before entering the strong-bits determination step 15. If all latest soft values of the data bits are strong, the error correction operation ends; otherwise, the flash memory is further read (in the step 16). In the example shown in FIG. 2B, the latest updated soft value of bit 3 is “10011101” which belongs to weak “1” category. As not all soft values of the data bits are strong in this example, a further read (the step 16) is performed. Data bits further read out of the flash memory in the step 16 are “11010110.”

Next, in the step 17, the soft values are respectively modified according to the further read-out bits and the latest soft values. Specifically, the soft value of each strong data bit is initialized if the further read-out bit is consistent with the previous bit. That is, the data bit “0” is initialized as (or mapped to) “00000000” (e.g., strong “0”) and the data bit “1” is initialized as (or mapped to) “11111111” (e.g., strong “1”). Otherwise, in one embodiment, the soft values are hold or kept unchanged. The operation in the step 17 according to the present embodiment is summarized in Table 3.

TABLE 3

| Further read-out | | |
|---|---|---|
| data bit | Latest soft value | Updated soft value |
| 0 | Strong “0” | 00000000 |
| | | (strong “0”) |
| 0 | Weak “0” | Hold |
| 0 | Weak “1” | Hold |
| 0 | Strong “1” | Hold |
| 1 | Strong “0” | Hold |
| 1 | Weak “0” | Hold |
| 1 | Weak “1” | Hold |
| 1 | Strong “1” | 11111111 |
| | | (strong “1”) |

In another embodiment, as shown in Table 4, in addition to initializing the soft value of each strong data bit if the further read-out bit is consistent with the previous bit, the soft value of weak data bit is enhanced or shifted if the further read-out bit is consistent with the previous bit. Specifically, the soft value of weak “1” with previous bit “1” is incremented by adding a first value (e.g., 00000111) to the latest soft value, provided no overflow occurs. On the other hand, the soft value of weak “0” with previous bit “0” is decremented by subtracting a second value (e.g., 00000111) from the latest soft value, provided no underflow occurs. The first value may, but not necessarily, be the same as the second value. Furthermore, the first value and the second value may be either predetermined or dynamically determined.

TABLE 4

| Further read-out | | |
|---|---|---|
| data bit | Latest soft value | Updated soft value |
| 0 | Strong “0” | 00000000 |
| | | (strong “0”) |
| 0 | Weak “0” | Latest value − |
| | | 00000111 |
| 0 | Weak “1” | Hold |
| 0 | Strong “1” | Hold |
| 1 | Strong “0” | Hold |
| 1 | Weak “0” | Hold |
| 1 | Weak “1” | Latest value + |
| | | 00000111 |
| 1 | Strong “1” | 11111111 |
| | | (strong “1”) |

After the soft values are modified in the step 17, they are subjected to further ECC decoding (e.g., the steps 13 and 14) as described above. With respect to each iteration in the ECC decoding, the soft value is correspondingly updated (in the step 14). In the example shown in FIG. 2B, the soft values are updated as LDPC3 and LDPC4 in sequence. It is observed that the soft value of bit 3 is updated to “00001101” which belongs to strong “0,” and the bit 3 is thus successfully corrected (from “1”) to “0.”

FIG. 2C is a detailed flow diagram that illustrates an error correction method for a memory device according to a modified embodiment of the present invention. The flow in FIG. 2C is similar to that in FIG. 2A except that, according to the modified embodiment in FIG. 2C, the strong-bits determination step 15 follows each iteration of the ECC decoding step 13 and the soft-value updating step 14.

Although specific embodiments have been illustrated and described, it will be appreciated by those skilled in the art that various modifications may be made without departing from the scope of the present invention, which is intended to be limited solely by the appended claims.

What is claimed is:

1. An error correction method for a memory device, comprising:
performing base reading of a memory device;
performing error correction code (ECC) decoding on data read out of the memory device; and
further reading the memory device when a result of the ECC decoding is not strongly determined;
wherein extra information acquired in the further reading of the memory device is used in the ECC decoding.

2. The method of claim 1, wherein the memory device is a flash memory.

3. The method of claim 1, wherein the base or further reading of the memory device iterates two or more times.

4. The method of claim 3, wherein different read thresholds are respectively used in the some iterations of the base or further reading of the memory device.

5. The method of claim 3, wherein each said ECC decoding performs concurrently with one said iteration of the further reading.

6. The method of claim 1, wherein the extra information comprises information directly read out of the flash memory, or previously stored information, or combination thereof.

7. The method of claim 1, wherein the ECC comprises low-density parity-check (LDPC) code.

8. The method of claim 7, a BCH code is concurrently accompanied with the LDPC code.

9. An error correction method for a memory device, comprising:
performing base reading of a memory device;
initializing soft values associated with data bits read out of the memory device;
performing at least one iteration of error correction code (ECC) decoding on the soft values;
updating the soft values with respect to each said iteration of the ECC decoding;
determining whether each said updated soft value is strong;
further reading the memory device when not all the updated soft values are strong; and
modifying the soft values according to read-out data bits of the further reading and the updated soft values.

10. The method of claim 9 further comprising:
performing further at least one iteration of the ECC decoding on the modified soft values.

11. The method of claim 10 further comprising:
further updating the soft values with respect to each said further performed iteration of the ECC decoding;
determining whether each said further updated soft value is strong.

12. The method of claim 9, wherein the soft value is classified into at least strong “1,” weak “1,” weak “0,” and strong “0.”

13. The method of claim 12, wherein the base reading is performed one time, and the soft value is initialized such that the data bit “0” read out of the memory device is mapped to the strong “0” and the data bit “1” read out of the memory device is mapped to the strong “1.”

14. The method of claim 12, wherein the base reading is performed at least two times, and the soft value is initialized according to all the read-out data bits of the at least two times of the base reading.

15. The method of claim 9, wherein the memory device is a flash memory.

16. The method of claim 9, wherein different read thresholds are respectively used in the iterations of the base or further reading of the memory device.

17. The method of claim 9, wherein the ECC comprises low-density parity-check (LDPC) code.

18. The method of claim 12, in the soft values modifying step, the strong soft value is initialized if the data bit read out in the further reading is consistent with the data bit in the updated soft value; and some of the other soft values are hold.

19. The method of claim 18, in the soft values modifying step, the weak soft value is enhanced if the data bit read out in the further reading is consistent with the data bit in the updated soft value.

20. The method of claim 19, wherein the weak “1” soft value is enhanced by adding a first value to the updated soft value; and the weak “0” soft value is enhanced by subtracting a second value from the updated soft value.
